(19) United States
(12) Patent Application Publication
(10) Pub. No.: US 2007/0161147 A1
(43) Pub. Date: Jul. 12, 2007

(54) Method of manufacturing CMOS image sensor

(75) Inventor: Yung Pil Kim, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/644,203

(22) Filed: Dec. 21, 2006

(30) Foreign Application Priority Data
Dec. 26, 2005 (KR) 10-2005-0129863

(51) Int. Cl. H01L 21/00

(52) U.S. Cl. 438/70; 257/E31.127

(57) ABSTRACT

Disclosed is a method of manufacturing a CMOS image sensor. The method includes the steps of forming a dielectric layer on a semiconductor substrate having a photodiode therein; forming a color filter array having a plurality of color filters on the dielectric layer; forming a plurality of micro-lenses on the color filter array, each micro-lens corresponding to one of the color filters; and performing a plasma surface treatment on the micro-lens.

### BACKGROUND OF INVENTION

1. Field of Invention

The present invention relates to a method for manufacturing a CMOS image sensor.

2. Description of Related Art

In general, an image sensor is a semiconductor device for converting optical images into electric signals, and can be classified into a charge coupled device (CCD) and a CMOS image sensor (CIS).

However, a CCD has various disadvantages, such as a complicated drive mode, highpower consumption, and so forth. Also, the CCD requires multiple photolithography processes, so the manufacturing process for the CCD is relatively complicated. Recently, the CMOS image sensor has been spotlighted as a next-generation image sensor capable of solving problems in the CCD.

The CMOS image sensor is a device employing a switching mode to sequentially detect an electric signal of each unit pixel by providing photodiodes and MOS transistors in unit pixels.

The CMOS image sensor according to the related art receives light through a micro-lens (not shown) and guides the light into photodiodes (not shown) by way of color filters (not shown). The photodiodes convert the light into electric signals, and the CMOS image sensor produces the image by processing the electric signals.

The micro-lens must have good light collecting and transmitting characteristics. Such characteristics may be affected by the profile or materials of the micro-lens.

However, according to the conventional art, the micro-lens may have weaknesses with regard to particles. That is, since the micro-lens has a small size, a particle may cause a defect in the image when the particle attaches to the micro-lens.

Especially, when the micro-lens includes an organic photoresist, since the organic photoresist has a relatively strong adhesion force, particles from external sources may be easily attached to the micro-lens.

Meanwhile, in order to fabricate the conventional CMOS image sensor, IC packages are cut into a desired size through a sawing process. When the semiconductor substrate is cut into the desired size, particles are generated during the cutting process, and the particles may easily attach to the micro-lens. Such particles attached to the micro-lens may not be so easily detached from the micro-lens. Thus, the particles may partially shield light that would otherwise enter the micro-lens, so that the image having a fault may be displayed.

### BRIEF SUMMARY OF THE INVENTION

Accordingly, the present invention has been made to solve the above-mentioned problems, and an object of the present invention is to provide a method of manufacturing an image sensor capable of preventing image fault by surface-treating a micro-lens such that particles can be prevented from adhering to the micro-lens.

To achieve the above object, the present invention provides a method of manufacturing a CMOS image sensor, the method comprising the steps of: forming a dielectric layer on a semiconductor substrate having a photodiode thereon; forming a color filter array having a plurality of color filters on the dielectric layer; forming a plurality of micro-lenses corresponding to the color filters on the color filter array; and performing plasma surface treatment on the micro-lens.

According to another aspect of the present invention, there is provided a method of manufacturing a CMOS image sensor, the method comprising the steps of: forming a dielectric layer on a semiconductor substrate having a photodiode therein; forming a color filter array having a plurality of color filters on the dielectric layer; forming a plurality of micro-lenses corresponding to the color filters on the color filter array; and performing an ashing process on the micro-lens using a predetermined gas.

### BRIEF DESCRIPTION OF DRAWINGS

FIGS. 1 to 6 are sectional views illustrating a method of manufacturing a CMOS image sensor according to a first embodiment of the present invention; and

FIG. 7 is a sectional view illustrating a method of manufacturing a CMOS image sensor according to a second embodiment of the present invention.

### DETAILED DESCRIPTION OF THE INVENTION

Hereinafter, a method of manufacturing a CMOS image sensor according to exemplary embodiments of the present invention will be described with reference to accompanying drawings.

In the following description, the expression “formed on [each, the, or a] layer” may include “formed directly on the layer,” “formed indirectly on the layer” and/or “formed over the layer”.

### Embodiment 1

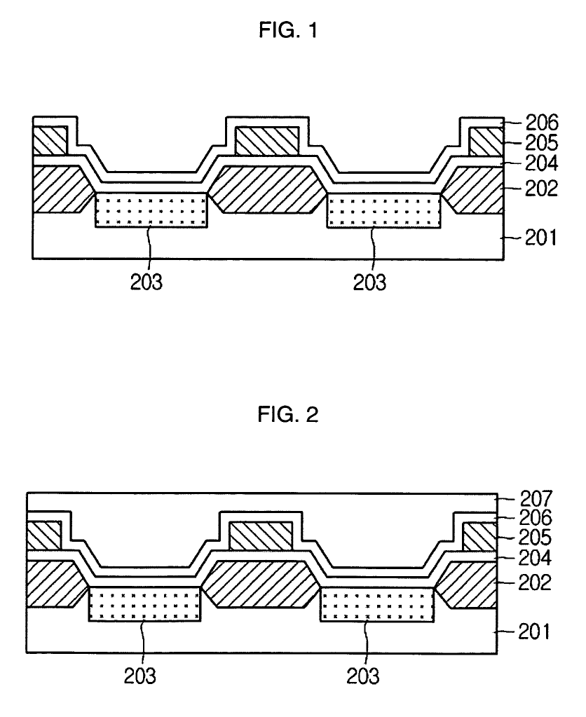

FIGS. 1 to 6 are sectional views illustrating a method of manufacturing a CMOS image sensor according to a first embodiment of the present invention.

As shown in FIG. 1, a field oxide layer 202 is formed on a semiconductor substrate 201 for the purpose of device isolation. Thus, a device area is defined between adjacent field oxide layers 202. The device area refers to (and thus includes) a unit pixel area.

A light receiving device (that is, a photodiode 203) is formed between the field oxide layers 202 in the unit pixel area, generally by one or more ion implantation processes using a photolithographically-patterned photoresist and/or a device structure as an implant mask. The light receiving device may include a photo gate in addition to the photodiode 203. Although only the photodiode is shown in the Figures, a series of devices forming the image sensor and its unit pixel structures and/or circuit elements, such as transistors, may be formed so as to receive, transmit and/or process the electric signals generated from the photodiode.

An interlayer dielectric layer 204 and a protective layer 206 are formed on a semiconductor substrate 201 including the photodiode 203. The protective layer 206 may have a stacked or multi-layer structure, instead of a single layer, where plural layers such as an oxide layer (which may be doped with fluorine or boron and/or phosphorous), a nitride layer, etc. are sequentially deposited.

Metal interconnection 205 is a signal line connected to the photodiode 203 so as to feed or transmit an electric signal detected from the photodiode 203 to a processing device (not shown)

Then, as shown in FIG. 2, a first planar layer 207 is formed on the protective layer 206 so as to reduce the topology (or step or height difference between various structures on the substrate) while improving adhesion for (or relative to) a color filter array formed in the subsequent process.

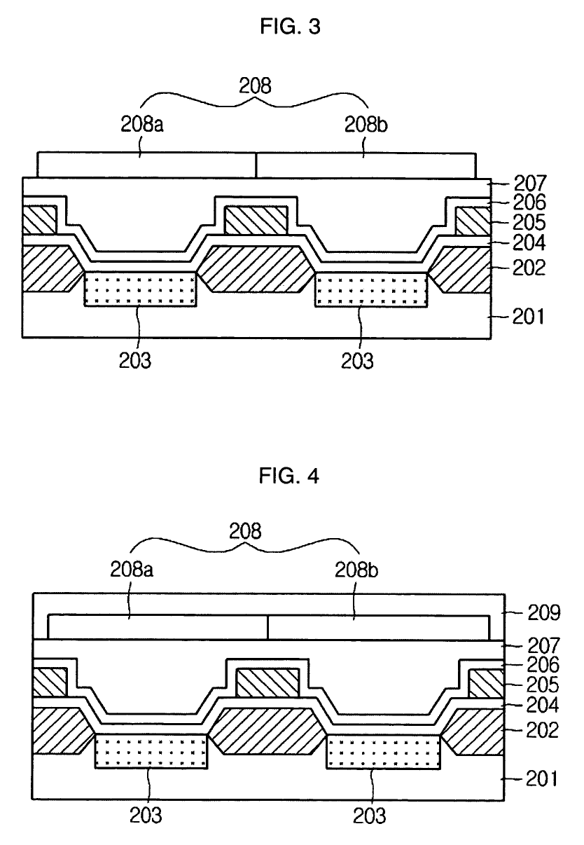

Then, as shown in FIG. 3, after coating a dyed photoresist on the first planar layer 207, a color filter array 208 including red, green or blue color filter 208a-208b is formed over each pixel area through a series of exposure and development processes. In other words, a first color filter layer (e.g., red, green or blue) is formed over the substrate, then is photolithographically patterned to form a first color filter (e.g., either 208a or 208b) over a first subset of active areas or unit pixels. This process is then repeated two more times to form filters for each of the other colors. Alternatively, the color filters may comprise yellow, magenta and cyan filters. The photodiodes 203 may correspond to the color filters 208a and 208b in a one-to-one relationship.

After that, as shown in FIG. 4, a second planar layer 209 is formed on the color filter array 208 so as to reduce a step difference between the color filters (e.g., 208a and 208b). The second planar layer 209 may include a photoresist film, an oxide layer or a nitride layer. Preferably, the second planar layer 209 has excellent transparency to visible light (e.g., in various embodiments, greater than 90%, 95%, or 98%).

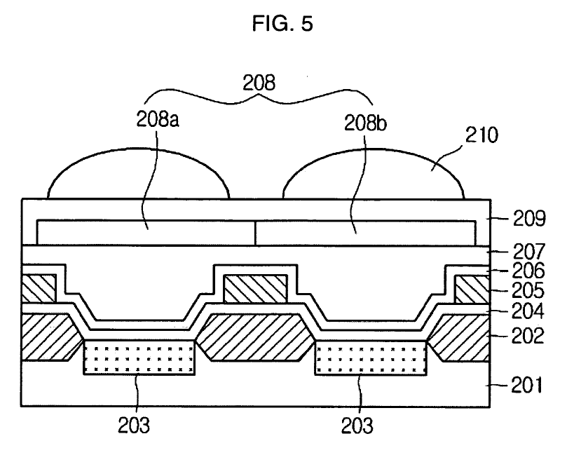

Then, as shown in FIG. 5, after coating a photoresist on the second planar layer 209, a plurality of micro-lenses 210 corresponding to the color filters 208a and 208b are formed through the exposure and development process. The micro-lenses 210 may focus the incident light from the exterior to the color filters 208a and 208b. Typically, each micro-lens 210 corresponds to a color filter (e.g., 208a or 208b) and a photodiode 203 in a one-to-one relationship.

Since the micro-lens 210 usually comprises or consists essentially of a photoresist, which is typically an organic substance, particles can be easily attached to the micro-lens 210. The particles attached to the micro-lens 210 may cause an image fault.

According to the first embodiment of the present invention, a plasma surface treatment is employed to solve the above problem.

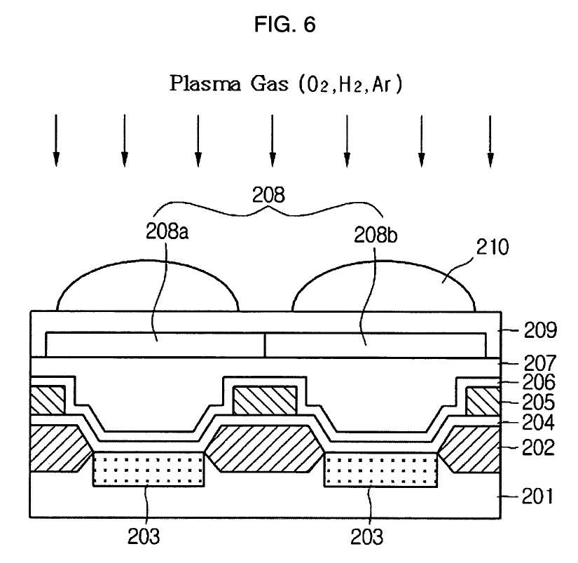

That is, as shown in FIG. 6, plasma surface treatment is performed on the micro-lenses 210. In general, the semiconductor substrate 201 with the micro-lenses 210, planarization layer 209, and color filter array 208 thereon is placed on a chuck (which may be electrostatic or vacuum) in a conventional plasma processing chamber and exposed to a plasma generated therein from a feed gas or feed gas mixture.

Such plasma surface treatment can be performed by using one or more of O₂, H₂, Ar, and N₂ as feed gas (es) . Additional feed gases may include other noble gases such as He, Ne and Kr, other oxygen-, nitrogen- and/or hydrogen-containing gases such as NO, N₂O, H₂O, O₃, NH₃, HF, etc. Through the plasma surface treatment, the property of the micro-lens 210 is changed in such a way that adhesion of the micro-lens 210 may be attenuated or reduced over the whole surface of the micro-lens 210.

That is, particles having high energy, generated due to the plasma in the plasma surface treatment chamber, may react with the micro-lens 210 so that the adhesion force is lowered at the surface of the micro-lens 210, thereby increasing a surface tension of the micro-lens 210. Alternatively, in some cases, the plasma treatment may effectively passivate the microlens surface to reduce an adhesive strength of the microlens surface.

In this manner, if the plasma surface treatment is performed relative to the semiconductor substrate 201 formed with the micro-lens 210, the adhesion property of the surface of the micro-lens 210 may be significantly lowered, so that the particles rarely attach (or at least attach at a lower incidence) to the surface of the micro-lens 210.

As described above, according to the present invention, the micro-lens is subject to a plasma surface treatment, so that the micro-lens is protected from particle adhesion, thereby preventing or reducing image faults.

### Embodiment 2

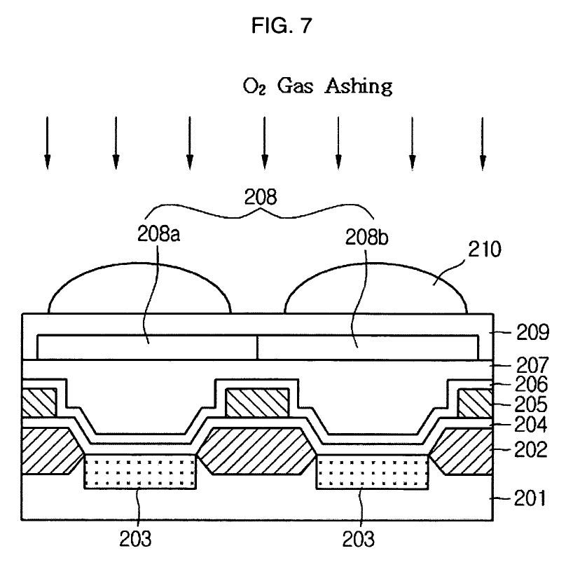

FIG. 7 is a sectional view illustrating a method of manufacturing a CMOS image sensor according to a second embodiment of the present invention.

Somewhat different from the first embodiment of the present invention, the second embodiment of the present invention performs an ashing process using a predetermined gas so as to prevent particles from sticking to the micro-lens 210.

That is, as shown in FIG. 7, the ashing process is performed on the semiconductor substrate 201 having the micro-lenses 210 thereon.

The ashing process is generally performed using O₂ gas or a gas mixture containing O₂ as a primary component (e.g., at least 10% by volume or total gas flow, optionally in combination with one or more noble gases such as He, Ne, Ar or Kr, and/or one or more oxygen-, nitrogen- and/or hydrogen-containing gases such as N₂, NO, N₂O, H₂O, O₃, NH₃, H₂, HF, etc.). Through the ashing process, the property of the micro-lens 210 is changed in such a way that adhesion of the micro-lens 210 may be attenuated or reduced over the whole surface of the micro-lens 210.

That is, particles having high energy, which are generated due to the ashing process, may react with the micro-lens 210 so that the adhesion force is lowered at the surface of the micro-lens 210, thereby increasing surface tension of the micro-lens 210.

In addition, when the ashing process is performed using O₂ gas, the entire surface of the micro-lens 210 may be slightly etched. Thus, the adhesion force may be lowered at the surface of the micro-lens 210 due to energy caused by the etching, so that the surface tension may be increased.

In this manner, if the ashing process is on the micro-lenses 210, the adhesion property of the surface of the micro-lenses 210 may be significantly lowered, so that the particles rarely attach (or attach at a lower incidence) to the surface of the micro-lenses 210.

In either case, plasma surface treatment and/or ashing may be conducted under conditions (such as temperature, pressure, feed gas flow rates, applied RF frequency and/or power, DC power, length of plasma exposure time, etc.) sufficient to reduce the adhesion of particles to the surface of the microlenses and/or reduce the number of particles on the microlenses, relative to otherwise identical CMOS image sensors that did not have such plasma surface treatment or ashing performed thereon. Selection and/or optimization of such conditions are within the abilities of those skilled in the art.

Although a preferred embodiment of the invention has been disclosed in the specification and the drawings, it is intended to not limit the scope of the present invention, but easily explain the technical teachings of the present invention and assist the understanding thereof. It will be obvious to those skilled in the art that variations and modifications of the disclosed embodiment can be made without departing from the spirit and scope of the invention based on the technical spirit of the present invention as set forth in the following claims.

1. A method of manufacturing a CMOS image sensor, the method comprising the steps of:
forming a dielectric layer on a semiconductor substrate having a photodiode therein;
forming a color filter array having a plurality of color filters on the dielectric layer;
forming a plurality of micro-lenses corresponding to the color filters on the color filter array; and
performing a plasma surface treatment on the micro-lenses.

2. The method as claimed in claim 1, wherein the plasma surface treatment increases a surface tension of the micro-lenses.

3. The method as claimed in claim 2, wherein the plasma surface treatment generates particles having a high energy that react with the micro-lenses to reduce an adhesion force at a surface of the micro-lenses, thereby increasing the surface tension of the micro-lenses.

4. The method as claimed in claim 3, wherein the plasma surface treatment comprises generating a plasma discharge using O₂ gas.

5. The method as claimed in claim 3, wherein the plasma surface treatment comprises generating a plasma discharge using N₂ gas.

6. The method as claimed in claim 3, wherein the plasma surface treatment comprises generating a plasma discharge using Ar gas.

7. The method as claimed in claim 3, wherein the plasma surface treatment comprises generating a plasma discharge using H₂ gas.

8. The method as claimed in claim 1, wherein each micro-lens corresponds to one of the color filters in the color filter array.

9. A method of manufacturing a CMOS image sensor, the method comprising the steps of:
forming a dielectric layer on a semiconductor substrate having a photodiode therein;
forming a color filter array having a plurality of color filters on the dielectric layer;
forming a plurality of micro-lenses corresponding to the color filters on the color filter array; and
performing an ashing process on the micro-lenses using a predetermined gas.

10. The method as claimed in claim 9, wherein the ashing process increases a surface tension of the micro-lenses.

11. The method as claimed in claim 10, wherein the ashing process generates particles having a high energy that react with the micro-lenses to reduce an adhesion force at a surface of the micro-lenses, thereby increasing the surface tension of the micro-lenses.

12. The method as claimed in claim 11, wherein the ashing process comprises using O₂ gas.

13. The method as claimed in claim 11, wherein the ashing process partially etches the surface of the micro-lenses.

14. The method as claimed in claim 9, wherein each micro-lens corresponds to one of the color filters in the color filter array. 15.
